(19) United States
(12) Patent Application Publication
(10) Pub. No.: US 2026/0114317 A1
(43) Pub. Date: Apr. 23, 2026

(54) SEMICONDUCTOR PACKAGE

(71) Applicant: MEDIATEK INC., Hsinchu City (TW)

(72) Inventors: Pei-Haw TSAO, Hsinchu City (TW); Li-Huan CHU, Hsinchu City (TW); Yu-Chih CHEN, Hsinchu City (TW); Shih-Chin LIN, Hsinchu City (TW); Te-Chi WONG, Hsinchu City (TW)

(21) Appl. No.: 19/357,292

(22) Filed: Oct. 14, 2025

Related U.S. Application Data
(60) Provisional application No. 63/708,800, filed on Oct. 18, 2024.

(51) Int. Cl. H01L 23/31; H01L 23/00; H01L 23/36; H01L 23/498

(52) U.S. Cl. CPC H10W 74/141; H10W 40/10; H10W 90/701; H10W 90/724

(57) ABSTRACT

A semiconductor package is provided. The semiconductor package includes a substrate, a die, and a molding compound. The die is mounted on the substrate. The molding compound is disposed on the substrate and surrounds the die. The molding compound includes a top surface and a first upper surface lower than the top surface. The die is exposed from the molding compound. The first upper surface of the molding compound is flush with a top surface of the die.

### CROSS REFERENCE TO RELATED APPLICATIONS

This application claims the benefit of U.S. provisional application No. 63/708,800, filed on Oct. 18, 2024, the entirety of which is incorporated by reference herein.

### TECHNICAL FIELD

The present disclosure relates to a semiconductor package, and, in particular, it relates to a molded ball-grid array semiconductor package.

### BACKGROUND

In order to ensure the continued miniaturization and multi-functionality of electronic products and communication devices, it is desired that semiconductor packages be small in size, support multi-pin connection, operate at high speeds, and have high functionality. This puts pressure on semiconductor package fabricators to develop fan-out semiconductor packages. However, electronic components inevitably generate heat during operation. Thus, how to dissipate the heat from an electronic component has become a crucial task for the industry.

Thus, a novel semiconductor package is needed.

### BRIEF SUMMARY

An embodiment of the present disclosure provides a semiconductor package. The semiconductor package includes a substrate, a die, and a molding compound. The die is mounted on the substrate. The molding compound is disposed on the substrate and surrounds the die. The molding compound includes a top surface and a first upper surface lower than the top surface. The die is exposed from the molding compound. The first upper surface of the molding compound is flush with a top surface of the die.

An embodiment of the present disclosure provides a semiconductor package. The semiconductor package includes a substrate, a die, and a molding compound. The die is mounted on the substrate. The molding compound is disposed on the substrate and surrounds the die. The die is exposed from the molding compound. The molding compound includes a top surface and a slanted side surface. The top surface of the die is lower than a top surface of the molding compound. The slanted side surface is connected between the top surface of the die and the top surface of the molding compound.

In addition, an embodiment of the present disclosure provides a semiconductor package. The semiconductor package includes a substrate, a die, and a molding compound. The die is mounted on the substrate. The molding compound is disposed on the substrate and surrounds the die. The die is exposed from the molding compound. The molding compound includes a top surface and an inner side surface connected to the top surface of the molding compound. The top surface and the inner side surface of the molding compound do not overlap a top surface of the die in a direction that is substantially perpendicular to the top surface of the die.

### BRIEF DESCRIPTION OF THE DRAWINGS

The present disclosure can be more fully understood by reading the subsequent detailed description and examples with references made to the accompanying drawings, wherein:

FIGS. 1, 2, 3, 4, 5, and 6 are cross-sectional views of a semiconductor package in accordance with some embodiments of the disclosure.

### DETAILED DESCRIPTION

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

With the increased usage of the semiconductor devices, satisfying power needs has become a priority. When the device power is getting higher, the thermal dissipation of the semiconductor device is highly concerned to avoid performance degradation of the semiconductor device induced by the high temperature. The conventional molded ball-grid array semiconductor package is fabricated as a structure in which the top surfaces of the exposed die and the molding compound are flush with each other and form as the top surface of the semiconductor package. In automotive applications, the thickness of the thermal interface material (TIM) dispensed between the exposed die and the heat sink above the die is difficult to control. Therefore, there is a need to further improve semiconductor packages to provide improved reliability.

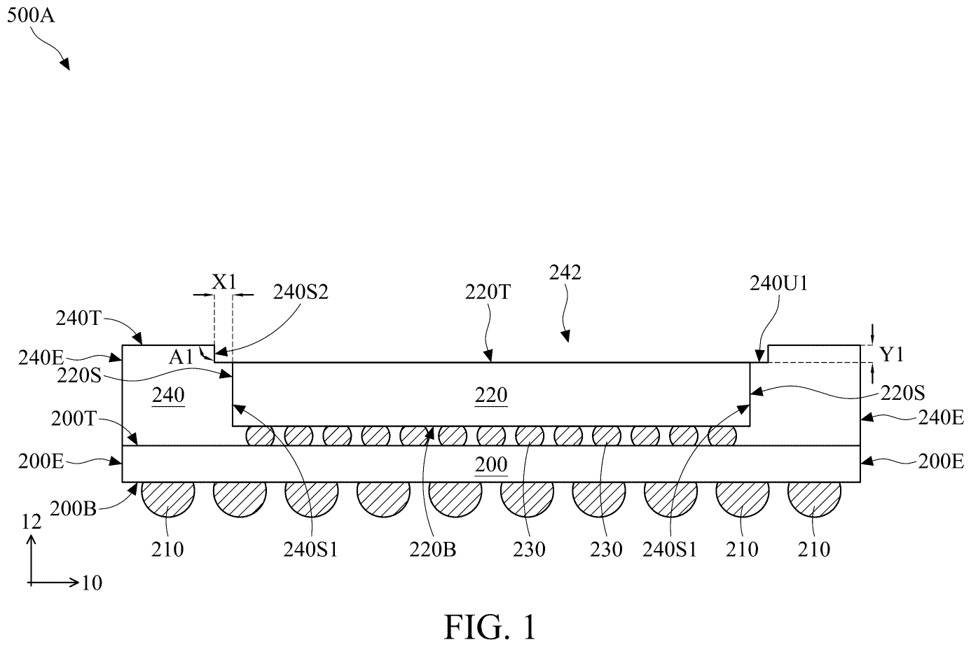

FIG. 1 is a cross-sectional view of a semiconductor package 500A in accordance with some embodiments of the disclosure. In some embodiments, the semiconductor package 500A is a portion of mobile phones, personal digital assistants (PDA), digital cameras, and servers, etc. The semiconductor package 500A is capable of applying to (or disposed on) a package requiring high-power operation, such as flip chip ball grid array (FCBGA), land grid array (LGA), fan-out package, three-dimensional (3D) integrated circuit (IC) package, etc. As show in FIG. 1, the semiconductor package 500A includes a substrate 200, a die 220, and a molding compound 240. In FIG. 1 and the following figures, direction 10 is defined as the horizontal direction (which is substantially perpendicular to the top surface 220T of the die 220 of the semiconductor package 500A), and direction 12 is defined as a vertical direction (which is substantially parallel to the top surface 220T of the die 220 of the semiconductor package 500A).

The substrate 200 can be a single layer or a multilayer structure. In some embodiments, the substrate 200 is, for example, a printed circuit board (PCB), an interposer, a package substrate, another semiconductor device or a semiconductor package. In some embodiments, the substrate 200 may be formed of the dielectric materials (e.g., polypropylene (PP), epoxy, polyimide, or other applicable resin materials) or semiconductor materials. The substrate 200 has a top surface 200T and a bottom surface 200B opposite the top surface 200T. The substrate 200 is provided for the die 220 disposed on the top surface 200T. A plurality of conductive traces (not shown), conductive vias and/or conductive pads (not shown) are disposed in the substrate 200. The conductive traces may be electrically connected to the corresponding conductive vias and conductive pads. The conductive pads and/or the conductive traces are exposed to openings of solder mask layers (not shown) disposed close to the top surface 200T and the bottom surface 200B. In one embodiment, the conductive traces may comprise power trace segments, signal trace segments or ground trace segments, which are used for the input/output (I/O) connections of the die 220. Also, the conductive pads are disposed on the top surface 200T and the bottom surface 200B of the substrate 200, connected to different terminals of the conductive traces. The conductive pads on the top surface 200T of the substrate 200 are used for the die 220 that is mounted directly on them.

The semiconductor package 500A further includes conductive structures 210 disposed on the bottom surface 200B of substrate 200 away from the die 220 and in contact with the corresponding the conductive pads (not shown) on the bottom surface 200B of the substrate 200. In some embodiments, the conductive structures 210 includes a conductive ball structure such as a solder ball, copper-core solder ball, a conductive bump structure such as a copper bump or a solder bump structure, or a conductive pillar structure such as a copper pillar structure.

As shown in FIG. 1, the die 220 is flipped to be disposed on the substrate 200 opposite the conductive structures 210 by a bonding process. The die 220 is mounted on the substrate 200 using conductive structures 230. In addition, the die 220 is electrically connected to the conductive structures 210 by the substrate 200.

The die 220 has a top surface 220T and a bottom surface 220B. Conductive pads (not shown) of the die 220 are disposed close to the bottom surface 220B to be electrically connected to the circuitry (not shown) of the die 220. Therefore, the bottom surface 220B of the die 220 also serves as an active surface of the die 220. In some embodiments, the die 220 is fabricated by a flip-chip technology. In addition, the die 220 is flipped to be disposed on the substrate 200 opposite the conductive structures 210. The bottom surface 220B (i.e., the active surface) of the die 220 may face the substrate 200.

In some embodiments, the die 220 includes a system-on-chip (SoC) die, a logic device, a memory device, a radio frequency (RF) device, the like, or any combination thereof. For example, the die 220 may include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or any combination thereof.

In some embodiments, the conductive structures 230 are electrically connected between the conductive pads (including conductive traces) of the substrate 200 and the die 220. In some embodiments, the conductive structures 230 include a conductive ball structure such as a solder ball, or a conductive structure such as a copper bump or a solder bump structure. For example, the conductive structures 230 may be controlled collapse chip connection (C4) structures. In some embodiments, each of the conductive structures 230 may include an under bump metallurgy (UBM) layer and a conductive ball structure on the under bump metallurgy (UBM) layer.

As shown in FIG. 1, the molding compound 240 is disposed on the top surface 200T of the substrate 200 and laterally surrounds the die 220 and the conductive structures 230. More specifically, the molding compound 240 fills the gap between the substrate 200 and the die 220, and extends upwardly to above the top surface 220T of the die 220. The molding compound 240 covers the bottom surface 220B of the die 220 and the top surface 200T of substrate 200. The molding compound 240 is also in contact with the bottom surface 220B of the die 220 and the top surface 200T of substrate 200. The molding compound 240 surrounds and completely covers side surfaces 220S of the die 220. The molding compound 240 may be in contact with the side surfaces 220S of the die 220. In addition, edges 240E of the molding compound 240 are level with the corresponding edges 200E of the substrate 200.

The molding compound 240 has a cavity 242 formed directly on the top surface 220T of the die 200. The entire top surface 220T of the die 220 is exposed from the cavity 242 of the molding compound 240. The top surface 220T of the die 220 may provide an additional thermal dissipating path to directly dissipate the heat from the die 220 to the outside environment.

In another aspect, the molding compound 240 includes a top surface 240T and a first upper surface 240U1. The first upper surface 240U1 is lower than the top surface 240T of the molding compound 240 and flush with the top surface 220T of the die 220. The first upper surface 240U1 may be adjacent to and surround the top surface 220T of the die 220. The top surface 240T and the first upper surface 240U1 of the molding compound 240 do not overlap the top surface 220T of the die 200 in the direction 12 that is substantially perpendicular to the top surface 220T of the die 220. In the direction 12, the first upper surface 240U1 is lower than the top surface 240T of the molding compound 240. In some embodiments, the distance (the vertical distance) Y1 in the direction 12 between the top surface 240T and the first upper surface 240U1 is between 40 μm and 300 μm. When the distance Y1 is within this range, the thickness and uniformity of the thermal interface material (TIM) on the top surface 220T of the die 220 can be more easily controlled. This allows the TIM to be thinner, improves the heat dissipation performance of the semiconductor package 500A, and prevents unnecessary increases in the total height.

As shown in FIG. 1, the molding compound 240 further includes opposite first side surfaces 240S1 and opposite second side surfaces 240S2 located inside the opposite edges 240E of the molding compound 240. Therefore, the first side surfaces 240S1 and the second side surfaces 240S2 may also serve as inner side surfaces 240S1 and 240S2 of the molding compound 240. Each of the first side surface 240S1 is in contact with corresponding side surface 220S of the die 220. In addition, each of the second side surface 240S2 is connected to the top surface 240T of the molding compound 240. In this embodiment, the first upper surface 240U1 is directly connected between the first side surface 240S1 and the second side surface 240S2. The first side surface 240S1 is separated from the second side surface 240S2 by a distance of X1 in the direction 10. In some embodiments, the distance X1 between the first side surface 240S1 and the second side surface 240S2 is between 40 μm and 300 μm. When the distance X1 is within this range, the molding compound 240 formed by the molding process can avoid covering the top surface 220T of the die 220, ensuring proper alignment between the mold and the die 220. This helps maintain good heat dissipation efficiency. Additionally, keeping the distance X1 within this range prevents unnecessary increases in the total width of the semiconductor package 500A.

In some embodiments, an angle A1 between the top surface 240T and the second side surface 240S2 of the molding compound 240 is a right angle or an obtuse angle. In this embodiment, the distance Y1 may also serve as the maximum depth of the cavity 242. When the angle A1 is a right angle, the depth of the cavity 242 may have a uniform value (i.e., the distance Y1).

In some embodiments, the molding compound 240 may be formed of a nonconductive material, such as an epoxy, a resin, a moldable polymer, or the like. In some embodiments, the molding compound 240 may be formed by a molding process including compression or injection process. For example, the molding compound 240 may be applied while substantially liquid, and then may be cured through a chemical reaction, such as in an epoxy or resin. In some other embodiments, the molding compound 240 may be an ultraviolet (UV) or thermally cured polymer applied as a gel or malleable solid capable of being disposed around the die 220, and then may be cured using a UV or thermally curing process. The molding compound 240 may be cured with a mold (not shown).

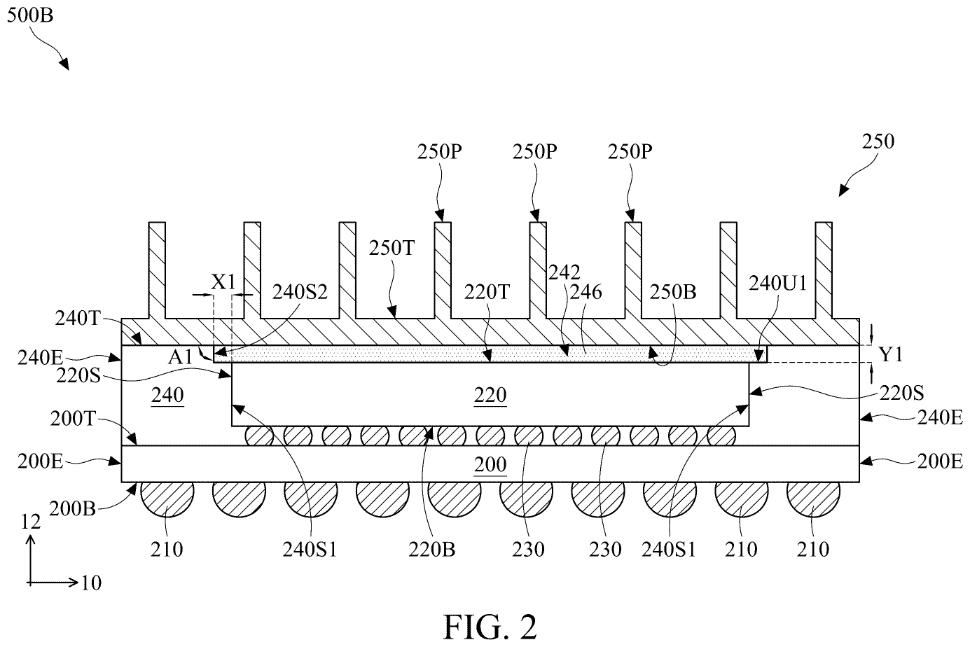

FIG. 2 is a cross-sectional view of a semiconductor package 500B in accordance with some embodiments of the disclosure. Elements of the embodiments that are the same or similar to those previously described with reference to FIG. 1 are not repeated herein, in the interests of brevity. As shown in FIGS. 1 and 2, the difference between the semiconductor package 500A and the semiconductor package 500B at least includes that the semiconductor package 500B further includes a thermal interface material (TIM) 246 and a heat sink 250.

The heat sink 250 is disposed on the die 220 and the molding compound 240. The heat sink 250 may be arranged on the top surface 240T of the molding compound 240 by an adhesive (not shown). In addition, the molding compound 240 may laterally (along the direction 10) extend over the molding compound 240 to cover the cavity 242. The heat sink 250 is not in contact with the first side surface 240S1, the second side surface 240S2 and the first upper surface 240U1 of the molding compound 240.

In some embodiments, the heat sink 250 may include at least one protrusion portion 250P. The protrusion portion 250P extends upwards form from an upper surface 250T of the 250P. In some embodiments, the fin-shaped protrusion portion 250P may increase the surface area of the heat sink 250. In addition, a bottom surface 250B of the heat sink 250 may be a flat surface. In some other embodiments, the heat sink 250 may be plate-shape with a uniform thickness. In some embodiments, the heat sink 250 may be formed of metal or ceramic.

As shown in FIG. 2, the TIM 246 is disposed between the heat sink 250 and the die 220. The TIM 246 is disposed in the cavity 242 of the molding compound 240 formed on the top surface 220T of the die 220 and surrounded by the second side surface 240S2 of the molding compound 240. In some embodiments, the top surface 220T of the die 220, the first upper surface 240U1 and the second side surface 240S2 of the molding compound 240 and the bottom surface 250B of the heat sink 250 may collectively form a closed space to accommodate the TIM 246. In some embodiments, the TIM 246 may substantially fill up the closed space. In addition, the TIM 246 is in contact with the top surface 220T of the die 220, the first upper surface 240U1 and the second side surface 240S2 of the molding compound 240 and the bottom surface 250B of the heat sink 250. In some embodiments, the TIM 246 is positioned within the cavity 242 of the molding compound 240. This design allows precise control over the thickness of the TIM 246, enabling its minimization and enhancing heat dissipation efficiency. Additionally, the cavity 242 helps prevent accidental movement or misalignment of the TIM 246, ensuring a secure and stable placement between the die 220 and the heat sink 250. As a result, this configuration contributes to a robust semiconductor package structure and consistent, efficient heat dissipation.

In some embodiments, the TIM 246 may include a metal or a metal alloy including Al, Cu, Ni, Co. In addition, the TIM 246 may include diamond, aluminum nitride, boron nitride, etc., or other high thermal conductivity material. In some embodiments, the TIM 246 may be made of a non-metallic material, such as a polymer. This non-metallic TIM has a higher thermal conductivity than the molding compound 240, enabling faster heat dissipation.

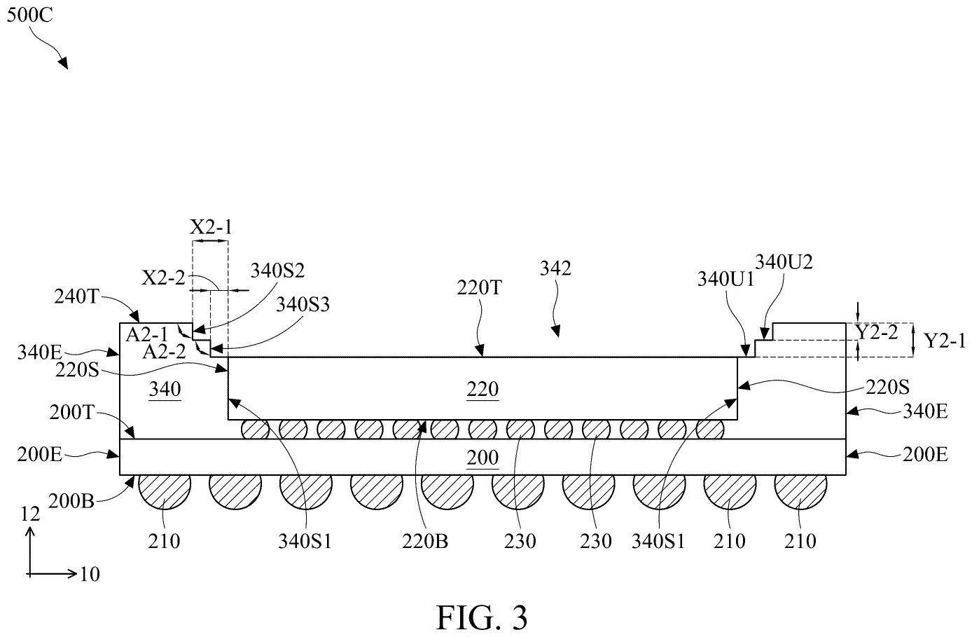

FIG. 3 is a cross-sectional view of a semiconductor package 500C in accordance with some embodiments of the disclosure. Elements of the embodiments that are the same or similar to those previously described with reference to FIG. 1 are not repeated herein, in the interests of brevity. As show in FIG. 3, the semiconductor package 500C includes a substrate 200, a die 220, and a molding compound 340. As shown in FIGS. 1 and 3, the difference between the semiconductor package 500A and the semiconductor package 500C at least includes that the molding compound 340 of the semiconductor package 500C has a cavity 342 having a different profile from the cavity 242 of the molding compound 240 of the semiconductor package 500a.

As shown in FIG. 3, the molding compound 340 is disposed on the top surface 200T of the substrate 200 and laterally surrounds the die 220 and the conductive structures 230. More specifically, the molding compound 340 fills the gap between the substrate 200 and the die 220, and extends upwardly to above the top surface 220T of the die 220. The molding compound 340 covers the bottom surface 220B of the die 220 and the top surface 200T of substrate 200. The molding compound 340 is also in contact with the bottom surface 220B of the die 220 and the top surface 200T of substrate 200. The molding compound 340 surrounds and completely covers side surfaces 220S of the die 220. The molding compound 340 may be in contact with the side surfaces 220S of the die 220. In addition, edges 340E of the molding compound 340 are level with the corresponding edges 200E of the substrate 200.

The molding compound 340 has the cavity 342 formed directly on the top surface 220T of the die 200. The entire top surface 220T of the die 220 is exposed from the cavity 342 of the molding compound 340.

In another aspect, the molding compound 340 includes a top surface 340T, a first upper surface 340U1 and a second upper surface 340U2. The first upper surface 340U1 is lower than the top surface 340T of the molding compound 340 and flush with the top surface 220T of the die 220. The first upper surface 340U1 is adjacent to and surrounds the top surface 220T of the die 220. The second upper surface 340U2 is higher than the top surface 220T of the die 220 and lower than the top surface 340T of the molding compound 340 in the direction 12. The second upper surface 340U2 of the molding compound 340 may be parallel to the top surface 340T of the molding compound 340 and/or the first upper surface 340U1 of the molding compound 340. The top surface 340T, the first upper surface 340U1 and the second upper surface 340U2 of the molding compound 340 do not overlap the top surface 220T of the die 200 in the direction 12.

In the direction 12, the first upper surface 340U1 is lower than the top surface 340T of the molding compound 340. The second upper surface 340U2 is lower than the top surface 340T of the molding compound 340. In some embodiments, the distance (the vertical distance) Y2-1 between the first upper surface 340U1 and the top surface 340T of the molding compound 340 in the direction 12 is between 40 μm and 300 μm. When the distance Y2-1 is within this range, the thickness and uniformity of the thermal interface material (TIM) on the top surface 220T of the die 220 can be more easily controlled. This allows the TIM to be thinner, improves the heat dissipation performance of the semiconductor package 500C, and prevents unnecessary increases in the total height In some embodiments, the distance (the vertical distance) Y2-2 between the second upper surface 340U2 and the top surface 340T of the molding compound 340 in the direction 12 is less than the distance Y2-1.

As shown in FIG. 3, the molding compound 340 further includes opposite first side surfaces 340S1, opposite second side surfaces 340S2 and opposite third side surfaces 340S3 located inside the opposite edges 340E of the molding compound 340. Therefore, the first side surfaces 340S1, the second side surfaces 340S2 and the third side surface 340S3 may also serve as inner side surfaces 340S1, 340S2 and 340S3 of the molding compound 340. Each of the first side surface 340S1 is in contact with corresponding side surface 220S of the die 220. Each of the second side surface 340S2 is directly connected between the top surface 340T and the second upper surface 340U2 of the molding compound 340. In addition, each of the third side surfaces 340S3 is directly connected between the first upper surface 340U1 and the second upper surface 340U2 of molding compound 340.

In this embodiment, the first upper surface 340U1 is directly connected between the first side surface 340S1 and the third side surfaces 340S3. The second upper surface 340U2 is directly connected between the second side surface 340S2 the third side surfaces 340S3. In the direction 10, the first side surface 340S1 is separated from the second side surface 340S2 by a distance of X2-1, and the first side surface 340S1 the first side surface 340S1 and the third side surfaces 340S3 the third side surfaces 340S3 by a distance of X2-2. In some embodiments, the distance X2-1 between the first side surface 340S1 and the second side surface 340S2 is between 40 μm and 300 μm. When the distance X2-1 is within this range, the molding compound 340 formed by the molding process can avoid covering the top surface 220T of the die 220, ensuring proper alignment between the mold and the die 220. This helps maintain good heat dissipation efficiency. Additionally, keeping the distance X2-1 within this range prevents unnecessary increases in the total width of the semiconductor package 500C. Furthermore, in some embodiments, the distance X2-2 between the first side surface 340S1 and the third side surface 340S3 is designed to be shorter than the distance X2-1. In some embodiments, the distance X2-2 between the first side surface 340S1 and the third side surfaces 340S3 is shorter than the distance X2-1.

In some embodiments, an angle A2-1 between the top surface 340T and the second side surface 340S2 of the molding compound 340 is a right angle or an obtuse angle. In some embodiments, the distance Y2-1 and the distance Y2-2 may also serve as first and second depths of the cavity 342. In addition, the distance Y2-1 may serve as the maximum depth of the cavity 342. When the angle A2-1 is a right angle, the cavity 342 of the molding compound 340 may have two fixed depths (i.e., the distance Y2-1 and the distance Y2-2).

In some embodiments, an angle A2-2 between the second upper surface 340U2 and the third side surfaces 340S3 of the molding compound 340 is a right angle or an obtuse angle.

In some embodiments, the material of the molding compounds 340 may be the same or similar to the material of the molding compound 240. The molding compounds 240 and 340 may be fabricated using the same or similar processes.

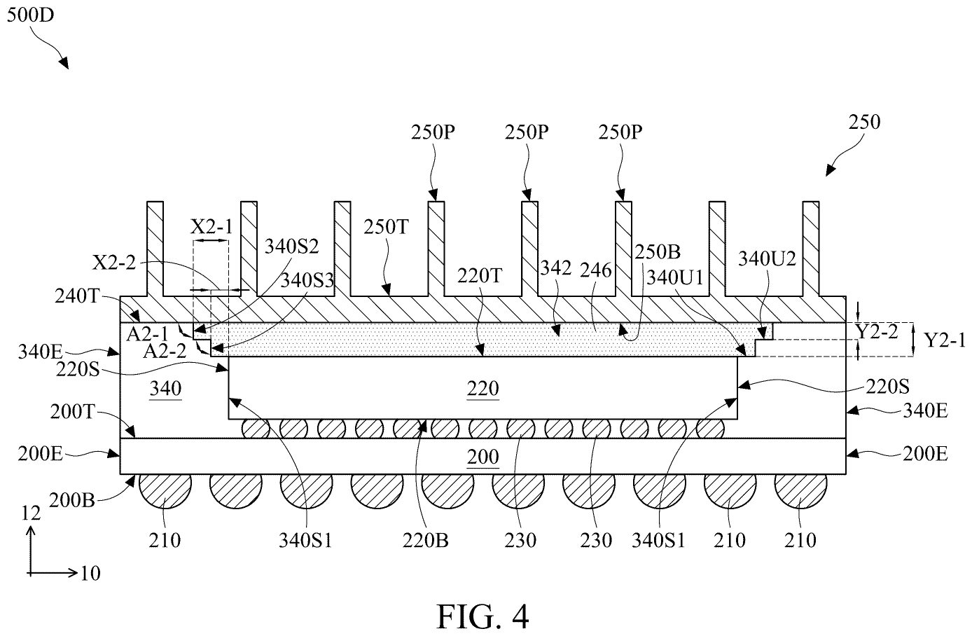

FIG. 4 is a cross-sectional view of a semiconductor package 500D in accordance with some embodiments of the disclosure. Elements of the embodiments that are the same or similar to those previously described with reference to FIG. 3 are not repeated herein, in the interests of brevity. As shown in FIGS. 3 and 4, the difference between the semiconductor package 500C and the semiconductor package 500D at least includes that the semiconductor package 500D further includes a thermal interface material (TIM) 246 and a heat sink 250.

The heat sink 250 is disposed on the die 220 and the molding compound 340. The heat sink 250 may be arranged on the top surface 340T of the molding compound 340 by an adhesive (not shown). In addition, the molding compound 340 may laterally (along a direction 10) extend over the molding compound 340 to cover the cavity 342. The heat sink 250 is not in contact with the first side surface 340S1, the second side surface 340S2, the third side surface 340S3, the first upper surface 340U1 and the second upper surface 340U2 of the molding compound 340.

In some embodiments, the heat sink 250 may include at least one protrusion portion 250P. The protrusion portion 250P extends upwards form from an upper surface 250T of the 250P. In some embodiments, the fin-shaped protrusion portion 250P may increase the surface area of the heat sink 250. In addition, a bottom surface 250B of the heat sink 250 may be a flat surface. In some other embodiments, the heat sink 250 may be plate-shape with a uniform (fixed) thickness.

As shown in FIG. 4, the TIM 246 is disposed between the heat sink 250 and the die 220. The TIM 246 is disposed in the cavity 342 of the molding compound 340 formed on the top surface 220T of the die 220 and surrounded by the second side surface 340S2, the second upper surface 340U2 and the third side surface 340S3 of the molding compound 340. In addition, the top surface 220T of the die 220, the second side surface 340S2, the second upper surface 340U2 and the third side surface 340S3 of the molding compound 340 and the bottom surface 250B of the heat sink 250 may collectively form a closed space to accommodate the TIM 246. In some embodiments, the TIM 246 may substantially fill up the closed space. In addition, the TIM 246 is in contact with the top surface 220T of the die 220, the second side surface 340S2, the second upper surface 340U2 and the third side surface 340S3 of the molding compound 340 and the bottom surface 250B of the heat sink 250. In some embodiments, the TIM 246 is positioned within the cavity 342 of the molding compound 340. This design allows precise control over the thickness of the TIM 246, enabling its minimization and enhancing heat dissipation efficiency. Additionally, the cavity 342 helps prevent accidental movement or misalignment of the TIM 246, ensuring a secure and stable placement between the die 220 and the heat sink 250. As a result, this configuration contributes to a robust semiconductor package structure and consistent, efficient heat dissipation.

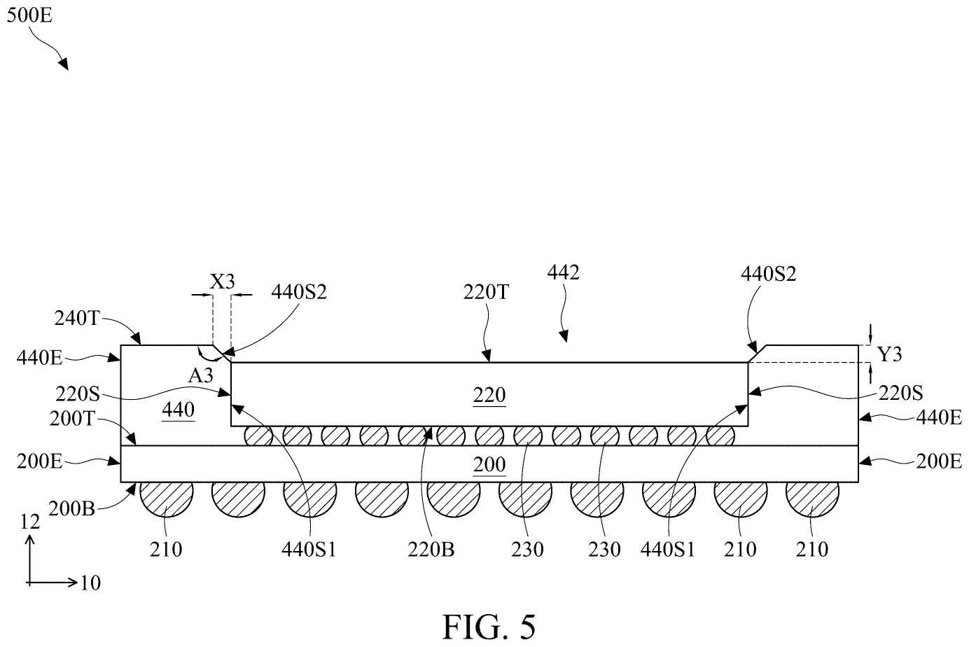

FIG. 5 is a cross-sectional view of a semiconductor package 500E in accordance with some embodiments of the disclosure. Elements of the embodiments that are the same or similar to those previously described with reference to FIG. 1 are not repeated herein, in the interests of brevity. As show in FIG. 5, the semiconductor package 500E includes a substrate 200, a die 220, and a molding compound 440. As shown in FIGS. 1 and 5, the difference between the semiconductor package 500A and the semiconductor package 500E at least includes that the molding compound 440 of the semiconductor package 500E has a cavity 442 having a different profile from the cavity 242 of the molding compound 240 of the semiconductor package 500A.

As shown in FIG. 5, the molding compound 440 is disposed on the top surface 200T of the substrate 200 and laterally surrounds the die 220 and the conductive structures 230. More specifically, the molding compound 440 fills the gap between the substrate 200 and the die 220, and extends upwardly to above the top surface 220T of the die 220. The molding compound 440 covers the bottom surface 220B of the die 220 and the top surface 200T of substrate 200. The molding compound 440 is also in contact with the bottom surface 220B of the die 220 and the top surface 200T of substrate 200. The molding compound 440 surrounds and completely covers side surfaces 220S of the die 220. The molding compound 440 may be in contact with the side surfaces 220S of the die 220. In addition, edges 440E of the molding compound 440 are level with the corresponding edges 200E of the substrate 200.

The molding compound 440 has a cavity 442 formed directly on the top surface 220T of the die 200. The entire top surface 220T of the die 220 is exposed from the cavity 442 of the molding compound 440.

As shown in FIG. 5, the molding compound 440 further includes opposite first side surfaces 440S1, and opposite second side surfaces 440S2 located inside the opposite edges 440E of the molding compound 440. Therefore, the first side surfaces 440S1 and the second side surfaces 440S2 may also serve as inner side surfaces 440S1 and 440S2 of the molding compound 440. Each of the first side surface 440S1 is in contact with corresponding side surface 220S of the die 220. Each of the second side surface 440S2 is directly connected between to the top surface 440T and the first side surface 440S1 of the molding compound 440. In addition, the second side surface 440S2 is adjacent to and surrounds the top surface 220T of the die 220.

In this embodiment, an angle A3 between the top surface 440T and the second side surface 440S2 of the molding compound 440 is an obtuse angle. The second side surface 440S2 may also serve as a slanted side surface 440S2. The slanted side surface 440S2 has a height Y3 in the direction 12 that is substantially perpendicular to the top surface 220T of the die 220 and a width X3 in the direction 10 that is substantially parallel to the top surface 220T of the die 220. In some embodiments, the width X3 measured in the direction 10 may be a direction substantially perpendicular to the corresponding first side surface 440S1 of the molding compound 440 or the corresponding side surface 220S of the die 220. In some embodiments, the height Y3 and the width X3 of the slanted side surface 440S2 are between 40 μm and 300 μm. When the height Y3 is within this range, the thickness and uniformity of the thermal interface material (TIM) on the top surface 220T of the die 220 can be more easily controlled. This allows the TIM to be thinner, improves the heat dissipation performance of the semiconductor package 500E, and prevents unnecessary increases in the total height. Similarly, when the width X3 is within this range, the molding compound 440 formed by the molding process can avoid covering the top surface 220T of the die 220, ensuring proper alignment between the mold and the die 220. This helps maintain good heat dissipation efficiency and prevents unnecessary increases in the total width of the semiconductor package 500E.

According to the range of the height Y3 and the width X3 of the slanted side surface 440S2, the angle A3 may be between 98 and 172 degrees. Since the angle A3 is an obtuse angle, the depth of the cavity 442 may be increased gradually to the maximum depth (i.e., the height Y3) of the cavity 442.

In some embodiments, the material of the molding compounds 440 may be the same or similar to the material of the molding compound 240. The molding compounds 240 and 440 may be fabricated using the same or similar processes.

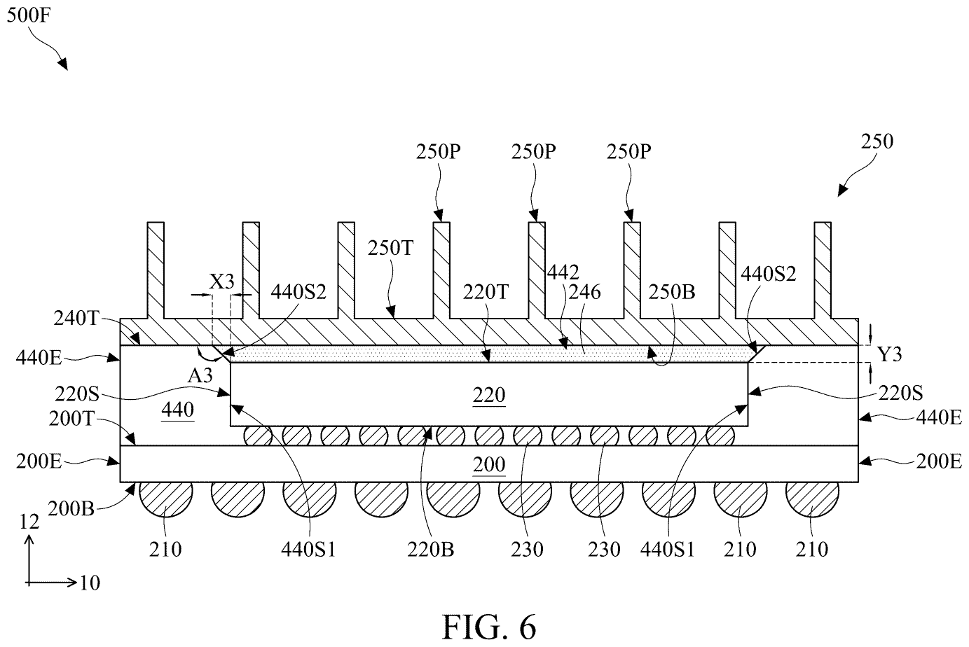

FIG. 6 is a cross-sectional view of a semiconductor package 500F in accordance with some embodiments of the disclosure. Elements of the embodiments that are the same or similar to those previously described with reference to FIG. 5 are not repeated herein, in the interests of brevity. As shown in FIGS. 5 and 6, the difference between the semiconductor package 500E and the semiconductor package 500F at least includes that the semiconductor package 500F further includes a thermal interface material (TIM) 246 and a heat sink 250.

The heat sink 250 is disposed on the die 220 and the molding compound 440. The heat sink 250 may be arranged on the top surface 440T of the molding compound 440 by an adhesive (not shown). In addition, the molding compound 440 may laterally (along a direction 10) extend over the molding compound 440 to cover the cavity 442. The heat sink 250 is not in contact with the first side surfaces 440S1 and the slanted side surface (the second side surface) 440S2 of the molding compound 440.

In some embodiments, the heat sink 250 may include at least one protrusion portion 250P. The protrusion portion 250P extends upwards form from an upper surface 250T of the 250P. In some embodiments, the fin-shaped protrusion portion 250P may increase the surface area of the heat sink 250. In addition, a bottom surface 250B of the heat sink 250 may be a flat surface. In some other embodiments, the heat sink 250 may be plate-shape with a uniform thickness.

As shown in FIG. 1, the TIM 246 is disposed between the heat sink 250 and the die 220. The TIM 246 is disposed in the cavity 442 of the molding compound 440 formed on the top surface 220T of the die 220 and surrounded by the second side surface 440S2 of the molding compound 440. In addition, the top surface 220T of the die 220, the second side surface 440S2 of the molding compound 440 and the bottom surface 250B of the heat sink 250 may collectively form a closed space to accommodate the TIM 246. In some embodiments, the TIM 246 may substantially fill up the closed space. In addition, the TIM 246 is in contact with the top surface 220T of the die 220, the second side surface 440S2 of the molding compound 440 and the bottom surface 250B of the heat sink 250.

The method for forming the semiconductor packages 500A, 500C and 500E may include the following steps. First, a die assembly carried by a carrier (not shown) is provided. In some embodiments, the die assembly includes the substrate 200 and the die 220 mounted on the substrate 200 by the conductive structures 230. In some embodiments, the die assembly may be formed by the following processes. First, the substrate 200 is disposed on the carrier. Next, flux (not shown) and conductive balls (not shown) are formed on the top surface 200T of the substrate 200 in sequence. Next, a pick and place process is performed to dispose the singulated die 220 on the conductive structures 230. Next, a reflow process is performed to reflow the conductive balls to form the conductive structures 230. The method further includes performing a molding process (including compression or injection process) with a mold chase (or a mold tool) to form a molding compound material (not shown) on the substrate 200 and filling the gap between the die 220 and the substrate 200. During the molding process, the mold chase (or a mold tool) is disposed directly on the die 220, and a release film (not shown) is interposed between the mold chase and the molding compound material. In some embodiments, the mold chase may have a protrusion portion (not shown) corresponding to the cavity of the resulting molding compound (including the cavity 242 of the molding compound 240, the cavity 342 of the molding compound 340, and the cavity 442 of the molding compound 440). Next, the molding compound material is cured to form the molding compound (including molding compound 240, 340 and 440). Next, the mold chase is removed to form the molding compound on the substrate 200 and surrounding the die 220. Next, the carrier is released form the substrate 200. The method further includes forming the conductive structures 210 on the bottom surface 200B of substrate 200.

The method for forming the semiconductor packages 500B, 500D and 500F may further includes the following steps after forming the semiconductor packages 500A, 500C and 500E. The TIM 246 is disposed in cavity of the resulting molding compound (including the cavity 242 of the molding compound 240, the cavity 342 of the molding compound 340, and the cavity 442 of the molding compound 440) and in contact with the top surface 220T of the die 220. Next, the heat sink 250 is disposed on the die 220 and the TIM 246, and connected to the top surface of the molding compound (including the top surfaces 240T, 340T, 440T of the molding compounds 240, 340, 440) by an adhesive (not shown).

The semiconductor package (e.g., the semiconductor packages 500A-500F) in accordance with some embodiments of the disclosure is fabricated as a structure in which the molding compound (e.g., the top surfaces 240T, 340T and 440T of the molding compounds 240, 340 and 440) has a cavity (e.g., the cavities 242, 342 and 442) to expose the die (e.g., the die 220), so that the top surface of the exposed die (e.g., the top surface 220T of the die 220) is lower than the top surface of the molding compound (e.g., the top surfaces 240T, 340T and 440T the molding compounds 240, 340 and 440). In some embodiments (e.g., the semiconductor packages 500B, 500D and 500F), the cavity of the molding compound (e.g., the cavities 242, 342 and 442 of the molding compounds 240, 340 and 440) located directly on the die can serve as a stress buffer region for the heat sink (e.g., the heat sink 250) disposed on the die 220. In addition, the cavity of the molding compound may have a fixed shape and predetermined depth(s). When the thermal interface material (TIM) (e.g., the thermal interface material 246) dispensed between the die and the heat sink. The TIM is limited in a closed space formed by the cavity of the molding compound and the heat sink 250. Therefore, the thickness of the TIM can be well-controlled. The reliability and heat dissipation efficiency of semiconductor package can be further improved.

Embodiments provide a semiconductor package. The semiconductor package includes a substrate, a die, and a molding compound. The die is mounted on the substrate. The molding compound is disposed on the substrate and surrounds the die. The molding compound includes a top surface and a first upper surface lower than the top surface. The die is exposed from the molding compound. The first upper surface of the molding compound is flush with a top surface of the die.

In some embodiments, the top surface and the first upper surface of the molding compound do not overlap the top surface of the die in a direction that is substantially perpendicular to the top surface of the die.

In some embodiments, a distance between the first upper surface and the top surface of the molding compound is between 40 μm and 300 μm.

In some embodiments, the molding compound further comprises a first side surface in contact with a side surface of the die and a second side surface connected to the top surface of the molding compound. A distance between the first side surface and the second side surface is between 40 μm and 300 μm.

In some embodiments, a first angle between the top surface and the second side surface of the molding compound is a right angle or an obtuse angle.

In some embodiments, the molding compound further comprises a second upper surface that is higher than the top surface of the die and lower than the top surface of the molding compound.

In some embodiments, the second upper surface of the molding compound is parallel to the top surface of the molding compound and/or the first upper surface of the molding compound.

In some embodiments, the molding compound further comprises a third side surface connected between the first upper surface and the second upper surface of molding compound.

In some embodiments, a second angle between the second upper surface and the second side surface of the molding compound is a right angle or an obtuse angle.

In some embodiments, the semiconductor package further includes a heat sink and a thermal interface material. The heat sink is disposed on the die and the molding compound. The thermal interface material is disposed between the heat sink and the die.

In some embodiments, the thermal interface material is disposed in a cavity of the molding compound formed on the top surface of the die and surrounded by the second side surface of the molding compound.

Embodiments provide a semiconductor package. The semiconductor package includes a substrate, a die, and a molding compound. The die is mounted on the substrate. The molding compound is disposed on the substrate and surrounds the die. The die is exposed from the molding compound. The molding compound includes a top surface and a slanted side surface. The top surface of the die is lower than a top surface of the molding compound. The slanted side surface is connected between the top surface of the die and the top surface of the molding compound.

In some embodiments, the top surface and the slanted side surface of the molding compound do not overlap the top surface of the die in a direction that is substantially perpendicular to the top surface of the die.

In some embodiments, the slanted side surface has a height in a direction that is substantially perpendicular to the top surface of the die and a width in a direction that is substantially perpendicular to the corresponding first side surface of the molding compound, and the height and the width of the slanted side surface are between 40 μm and 300 μm.

In some embodiments, a first angle between the top surface and the slanted side surface of the molding compound is between 98 degrees and 172 degrees.

In some embodiments, the semiconductor package further includes a heat sink and a thermal interface material. The heat sink is disposed on the die and the molding compound. The thermal interface material is disposed between the heat sink and the die.

In some embodiments, the thermal interface material is disposed in a cavity of the molding compound formed on the top surface of the die and surrounded by the slope of the molding compound.

Embodiments provide a semiconductor package. The semiconductor package includes a substrate, a die, and a molding compound. The die is mounted on the substrate. The molding compound is disposed on the substrate and surrounds the die. The die is exposed from the molding compound. The molding compound includes a top surface and an inner side surface connected to the top surface of the molding compound. The top surface and the inner side surface of the molding compound is free from overlapping a top surface of the die in a direction that is substantially perpendicular to the top surface of the die.

In some embodiments, the molding compound further comprises a first upper surface that is lower than the top surface of the molding compound and flush with a top surface of the die, and the inner side surface is connected between the top surface and the first upper surface.

In some embodiments, the inner side surface is a slanted side surface directly connected between the top surface of the die and the top surface of the molding compound.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor package, comprising:
a substrate;
a die mounted on the substrate; and
a molding compound disposed on the substrate and surrounding the die, wherein the molding compound comprises a top surface and a first upper surface lower than the top surface,
wherein the die is exposed from the molding compound, and the first upper surface of the molding is flush with a top surface of the die.

2. The semiconductor package as claimed in claim 1, wherein the top surface and the first upper surface of the molding compound do not overlap the top surface of the die in a direction that is substantially perpendicular to the top surface of the die.

3. The semiconductor package as claimed in claim 1, wherein a distance between the first upper surface and the top surface of the molding compound is between 40 μm and 300 μm.

4. The semiconductor package as claimed in claim 1, wherein the molding compound further comprises a first side surface in contact with a side surface of the die, and a second side surface connected to the top surface of the molding compound, and wherein a distance between the first side surface and the second side surface is between 40 μm and 300 μm.

5. The semiconductor package as claimed in claim 4, wherein a first angle between the top surface and the second side surface of the molding compound is a right angle or an obtuse angle.

6. The semiconductor package as claimed in claim 1, wherein the molding compound further comprises a second upper surface that is higher than the top surface of the die and lower than the top surface of the molding compound.

7. The semiconductor package as claimed in claim 6, wherein the second upper surface of the molding compound is parallel to the top surface of the molding compound.

8. The semiconductor package as claimed in claim 6, wherein the molding compound further comprises a third side surface connected between the first upper surface and the second upper surface of molding compound.

9. The semiconductor package as claimed in claim 8, wherein a second angle between the second upper surface and the third side surface of the molding compound is a right angle or an obtuse angle.

10. The semiconductor package as claimed in claim 4, further comprising:
a heat sink disposed on the die and the molding compound; and
a thermal interface material disposed between the heat sink and the die.

11. The semiconductor package as claimed in claim 10, wherein the thermal interface material is disposed in a cavity of the molding compound formed on the top surface of the die and surrounded by the second side surface of the molding compound.

12. A semiconductor package, comprising:
a substrate;
a die mounted on the substrate; and
a molding compound disposed on the substrate and surrounding the die,
wherein the die is exposed from the molding compound, and wherein the molding compound comprises a top surface higher than a top surface of the die, and a slanted side surface connected between the top surface of the die and the top surface of the molding compound.

13. The semiconductor package as claimed in claim 12, wherein the top surface and the slanted side surface of the molding compound do not overlap the top surface of the die in a direction that is substantially perpendicular to the top surface of the die.

14. The semiconductor package as claimed in claim 12, wherein the slanted side surface has a height in a direction that is substantially perpendicular to the top surface of the die and a width in a direction that is substantially perpendicular to the corresponding first side surface of the molding compound, and the height and the width of the slanted side surface are between 40 μm and 300 μm.

15. The semiconductor package as claimed in claim 12, wherein a first angle between the top surface and the slanted side surface of the molding compound is between 98 degrees and 172 degrees.

16. The semiconductor package as claimed in claim 12, further comprising:
a heat sink disposed on the die and the molding compound; and
a thermal interface material disposed between the heat sink and the die.

17. The semiconductor package as claimed in claim 16, wherein the thermal interface material is disposed in a cavity of the molding compound formed on the top surface of the die and surrounded by the slanted side surface of the molding compound.

18. A semiconductor package, comprising:
a substrate;
a die mounted on the substrate; and
a molding compound disposed on the substrate and surrounding the die,
wherein the molding compound comprises a top surface and an inner side surface connected to the top surface of the molding compound, and wherein the top surface and the inner side surface of the molding compound is free from overlapping a top surface of the die in a direction that is substantially perpendicular to the top surface of the die.

19. The semiconductor package as claimed in claim 18, wherein the molding compound further comprises a first upper surface lower than the top surface of the molding compound and flush with the top surface of the die, and the inner side surface is connected between the top surface and the first upper surface.

20. The semiconductor package as claimed in claim 18, wherein the inner side surface is a slanted side surface directly connected between the top surface of the die and the top surface of the molding compound.
